(19) United States
(12) Patent Application Publication
(10) Pub. No.: US 2025/0239514 A1
(43) Pub. Date: Jul. 24, 2025

(54) SEMICONDUCTOR PACKAGES WITH REINFORCEMENT STRUCTURES

(71) Applicant: Taiwan Semiconductor Manufacturing Co., Ltd., Hsinchu (TW)

(72) Inventors: Cong-Wei Yang, New Taipei City (TW); Chin-Hua Wang, New Taipei City (TW); Tsung-Yen Lee, Hemei Township (TW); Shin-Puu Jeng, Hsinchu (TW); Kathy Wei Yan, Hsinchu (TW)

(21) Appl. No.: 18/619,758

(22) Filed: Mar. 28, 2024

Related U.S. Application Data
(60) Provisional application No. 63/624,511, filed on Jan. 24, 2024.

(51) Int. Cl. H01L 23/498; H01L 23/00; H01L 23/31; H01L 25/00; H01L 25/065

(52) U.S. Cl. CPC H01L 23/49838; H01L 23/3128; H01L 23/49866; H01L 25/0655; H01L 25/50; H01L 24/16; H01L 24/32; H01L 24/73; H01L 24/94; H01L 2224/16225; H01L 2224/32225; H01L 2224/73204; H01L 2224/94; H01L 2924/1815

(57) ABSTRACT

A method includes attaching a first package component to a substrate, wherein the first package component includes an interposer; dies on the interposer; and a molding material surrounding the dies; and attaching reinforcement structures to top surfaces of the dies, wherein the molding material is free of the reinforcement structures.

### PRIORITY CLAIM AND CROSS-REFERENCE

This application claims the benefit of U.S. Provisional Application No. 63/624,511, filed on Jan. 24, 2024, which application is hereby incorporated herein by reference.

### BACKGROUND

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed. For example, one problem of concern is stress within a package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, and 6 illustrate cross-sectional views of intermediate steps in the formation of a package component, in accordance with some embodiments.

FIGS. 7 and 8 illustrate a cross-sectional view and a plan view of an intermediate step in the formation of a package, in accordance with some embodiments.

FIGS. 9 and 10 illustrate a cross-sectional view and a plan view of an intermediate step in the formation of reinforcement structures on a package component, in accordance with some embodiments.

FIGS. 11A, 11B, 11C, and 11D illustrate plan views of reinforcement structures on package components, in accordance with some embodiments.

FIG. 12 illustrates a plan view of reinforcement structures on a package component, in accordance with some embodiments.

FIGS. 13A, 13B, and 13C illustrate plan views of reinforcement structures on package components, in accordance with some embodiments.

FIGS. 14A and 14B illustrate plan views of reinforcement structures on package components, in accordance with some embodiments.

FIGS. 15 and 16 illustrate a cross-sectional view and a plan view of an intermediate step in the formation of a package, in accordance with some embodiments.

FIGS. 17 and 18 illustrate a cross-sectional view and a plan view of an intermediate step in the formation of a package, in accordance with some embodiments.

FIG. 19 illustrates a cross-sectional view of an intermediate step in the formation of a package, in accordance with some embodiments.

FIGS. 20 and 21 illustrate a cross-sectional view and a plan view of an intermediate step in the formation of a package, in accordance with some embodiments.

FIGS. 22 and 23 illustrate cross-sectional views of intermediate steps in the formation of a package component, in accordance with some embodiments.

FIG. 24 illustrates a cross-sectional view of an intermediate step in the formation of a package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

In accordance with some embodiments of the present disclosure, reinforcement structures are attached to a package component to provide support and reduce thermally-induced stress within the package component. The thermally-induced stress may be due to Coefficient of Thermal Expansion (CTE) mismatch between the package component and an underlying substrate. In some embodiments, the reinforcement structures are placed near corners of devices within the package component to reduce thermally-induced stress in these regions. In this manner, stress-induced damage within the package component such as cracking or warping may be reduced, which can improve reliability and yield. The techniques described herein may apply to a variety of packaging technologies, such as System on an Integrated Circuit (SoIC) technology or the like.

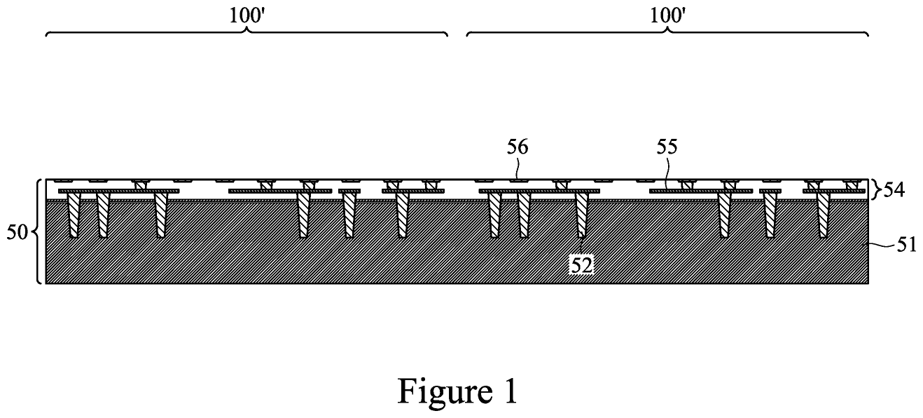

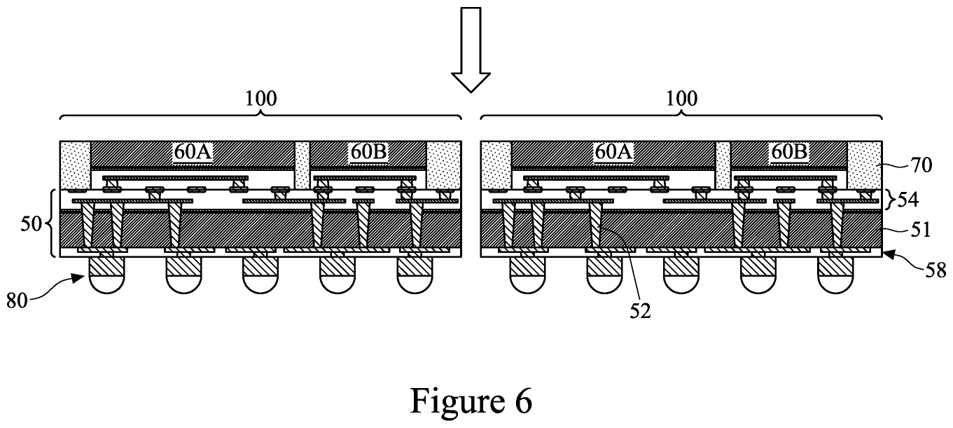

FIGS. 1 through 6 illustrate intermediate steps in the formation of a package component 100 (see FIG. 6), in accordance with some embodiments. Multiple package components 100 may be at least partially formed on a single wafer 50 and then subsequently singulated into individual package components 100. Accordingly, FIGS. 1-5 indicate package regions 100′ within which the individual package components 100 are formed.

In FIG. 1, a wafer 50 is formed or provided, in accordance with some embodiments. The wafer 50 may be processed according to applicable manufacturing processes to form devices, integrated circuit dies, interconnect structures, interposers, or the like within the package regions 100′ of the wafer 50. In some embodiments, the wafer 50 may be an interposer or the like. In accordance with some embodiments, the wafer 50 may include a substrate 51, through-substrate vias (TSVs) 52, and an interconnect structure 54. The substrate 51 may be a semiconductor substrate, such as a bulk semiconductor, a semiconductor-on-insulator (SOI) substrate, or the like, which may be doped (e.g., with a p-type or an n-type dopant) or undoped. The substrate 51 may be a wafer, such as a silicon wafer. Other substrates, such as a silicon-on-insulator (SOI) substrate, a multi-layered substrate, or a gradient substrate may also be used. In some embodiments, the semiconductor material of the substrate 51 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. As described previously, multiple package components 100 may be formed on the same substrate 51 and then subsequently separated into individual package components 100 using a singulation process (e.g., a sawing process, dicing process, or the like).

Further, integrated circuit devices (not separately illustrated) may be formed at a front-side surface of the substrate 51, in some embodiments. The integrated circuit devices may include active devices (e.g., NMOS and PMOS transistors, diodes, etc.), passive devices (e.g., resistors, capacitors, etc.), and the like. In addition, TSVs 52 may be formed extending partially through the substrate 51. In other embodiments, active devices and/or passive devices are not formed in the wafer 50.

In some embodiments, an interconnect structure 54 is formed over the front-side of the substrate 51. The interconnect structure 54 includes conductive features 55 formed in one or more dielectric layers (not separately illustrated). The conductive features 55 may comprise, for example conductive lines, conductive vias, conductive pads, metallization patterns, redistribution layers, or the like. In some embodiments, the conductive features 55 include bonding pads 56 formed at the front-side surface of the interconnect structure 54. Conductive features 55 of the interconnect structure 54 may be electrically connected to the integrated circuit devices and/or the TSVs 52. In some cases, the TSVs 52 may extend into the interconnect structure 54. The conductive features 55 may be formed using a damascene process, a dual damascene process, or another suitable technique. The conductive features 55 may comprise, for example, copper, aluminum, tungsten ruthenium, cobalt, alloys thereof, combinations thereof, or the like. The dielectric layers may be formed of or comprise dielectric materials such as polymer, silicon nitride, silicon oxide, silicon oxynitride, silicon oxycarbide, silicon carbonitride, the like, combinations thereof, and/or multi-layers thereof. In some embodiments, the dielectric layers may comprise one or more materials such as Phospho-Silicate Glass (PSG), Boro-Silicate Glass (BSG), Boron-Doped Phospho-Silicate Glass (BPSG), undoped Silicate Glass (USG), low-k dielectric materials, or the like. Other materials are possible. In some cases, the dielectric layers may be Inter-Metal Dielectric (IMD) layers. The interconnect structure 54 shown in FIG. 1 is an example, and an interconnect structure 54 may have different features or have a different configuration than shown. In some embodiments, the interconnect structure 54 may comprise a seal ring (not shown).

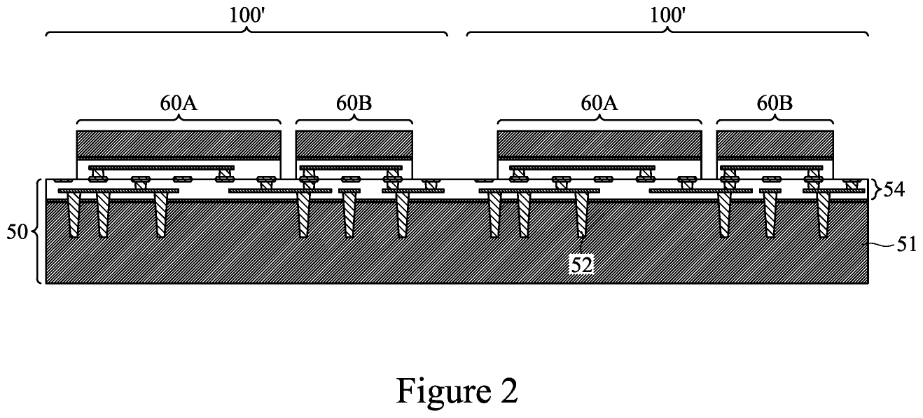

In FIG. 2, devices 60 are bonded to the interconnect structure 54 of the wafer 50, in accordance with some embodiments. As an example, FIG. 2 illustrates two devices 60 within each package region 100′, indicated as device 60A and device 60B, but in other embodiments more or fewer devices 60 may be present within each package region 100′. A device 60 may include, for example, a chip, a die, a semiconductor device, an integrated circuit die, a system-on-chip (SoC) device, a system-on-integrated-circuit (SoIC) device, a package, the like, or a combination thereof. In some embodiments, a device 60 comprises a logic die (e.g., central processing unit (CPU, xPU), graphics processing unit (GPU), a system-on-a-chip (SoC), an application processor (AP), microcontroller, etc.), a memory die (e.g., dynamic random access memory (DRAM) die, static random access memory (SRAM) die, a hybrid memory cube (HMC) die, a high bandwidth memory (HBM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), a BaseBand (BB) die, a photonic integrated circuit, a photonic package, a photonic die, the like, or combinations thereof. Other types of device 60 are possible. The devices 60A and 60B may be similar types of devices or may be different types of devices, and may have similar dimensions or different dimensions.

In some embodiments, the devices 60 are attached to the wafer 50 using a direct bonding process, such as fusion bonding, dielectric-to-dielectric bonding, and/or metal-to-metal bonding. In accordance with some embodiments, the bonding of the devices 60 to the wafer 50 includes pre-treating the bonding surfaces of the devices 60 and/or the bonding surfaces of the interconnect structure 54 with a process gas comprising oxygen (O₂) and/or nitrogen (N₂), performing a pre-bonding process to bond the bonding surfaces together, and then performing an annealing process to strengthen the bond. The bonding surfaces of the interconnect structure 54 may comprise, for example, exposed surfaces of a dielectric bonding layer of the interconnect structure and exposed surfaces of the bonding pads 56. The bonding surfaces of the devices 60 may comprise, for example, exposed surfaces of dielectric bonding layers and exposed surfaces of metal bonding pads.

In accordance with some embodiments, during the pre-bonding process, the bonding surfaces of the devices 60 are put into physical contact with the bonding surfaces of the interconnect structure 54. Metal bonding pads of the devices 60 may be put into physical contact with corresponding bonding pads 56 of the interconnect structure 54. A pressing force may be applied to press the devices 60 against the interconnect structure 54. The pre-bonding process may be performed at room temperature (e.g., in the range from about 20° C. to about 25° C.), though a higher temperature may also be used. After the pre-bonding process, an annealing process is performed to bond the devices 60 to the interconnect structure 54. Dielectric bonding surfaces of the devices 60 are bonded to the dielectric bonding surfaces of the interconnect structure 54 by dielectric-to-dielectric bonds, and metal bonding pads of the devices 60 are bonded to bonding pads 56 of the interconnect structure by metal-to-metal bonds. In accordance with some embodiments, the annealing process is performed at a temperature in a range from 150° C. to 350° C. The annealing duration may be in a range from 30 minutes to 60 minutes. Other bonding techniques are possible.

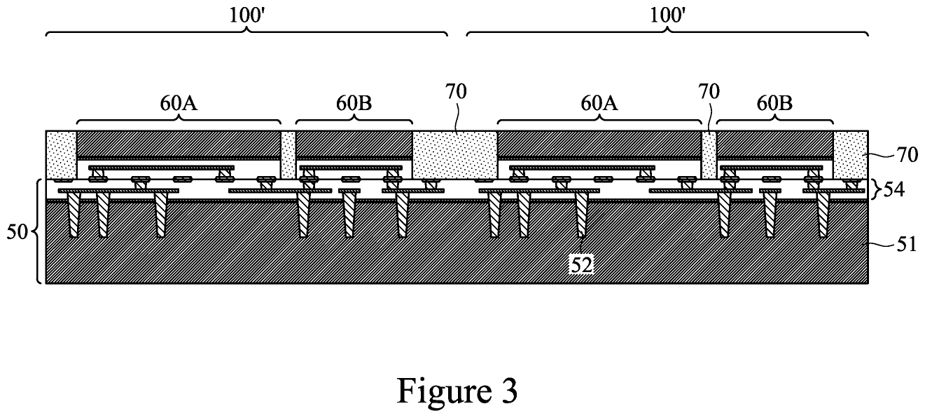

In FIG. 3, a molding material 70 is deposited on the wafer 50 and between the devices 60, in accordance with some embodiments. The molding material 70 may be deposited over the wafer 50, over the devices 60, and between adjacent devices 60 (e.g., between neighboring devices 60A and 60B). The molding material 70 may laterally surround each device 60. The molding material 70 may comprise a molding compound, an encapsulant, an epoxy, a polymer, a composite material, a silicon oxide filler material, or the like. The molding material 70 may be applied by compression molding, transfer molding, deposition, or the like. The molding material 70 may be applied in liquid or semi-liquid form and then subsequently cured. In some embodiments, a planarization process, such as a CMP process or a grinding process, may be performed to remove excess portions of the molding material 70. In some embodiments, the planarization process exposes the devices 60, and top surfaces of the devices 60 and the molding material 70 are substantially level after performing the planarization process.

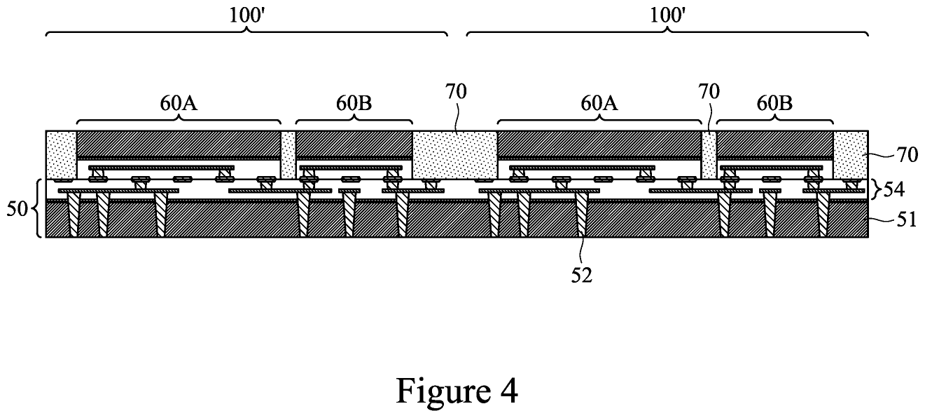

In FIG. 4, the back-side of the substrate 51 is thinned to expose the TSVs 52, in accordance with some embodiments. The substrate 51 may be thinned using a planarization process (e.g., a CMP process and/or a grinding process), an etching process, the like, or a combination thereof.

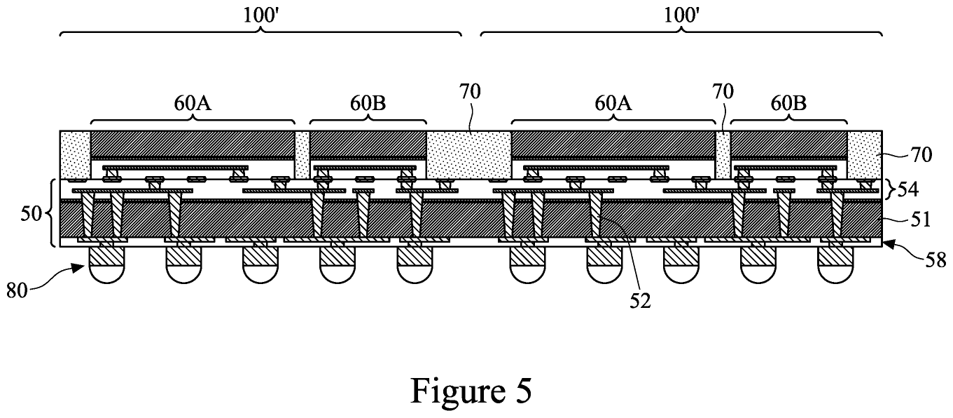

In FIG. 5, a redistribution structure 58 is formed on the back-side of the substrate 51, and conductive connectors 80 are formed on the redistribution structure 58, in accordance with some embodiments. The redistribution structure 58 includes one or more metallization layers (e.g., redistribution layers, redistribution lines, or the like) formed in one or more dielectric layers (not individually labeled). Metallization layers of the redistribution structure 58 are electrically connected to the TSV 52. Specifically, the metallization layers are connected to the devices 60 by the TSVs 52 and the interconnect structure 54. The illustrated redistribution structure 58 is an example, and may include more or fewer dielectric layers and/or metallization layers than illustrated.

The dielectric layer(s) of the redistribution structure 58 are formed of one or more suitable dielectric materials, such as a polymer, which may be a photosensitive material such as PBO, polyimide, a BCB-based polymer, or the like, which may be patterned using a lithography mask. In other embodiments, the dielectric layer(s) are formed of an oxide such as silicon oxide, PSG, BSG, BPSG; a nitride such as silicon nitride; a combination thereof such as silicon oxynitride; or the like. The dielectric layer(s) may be formed by spin coating, lamination, Chemical Vapor Deposition (CVD), the like, or a combination thereof. After each dielectric layer is formed, it may then be patterned to expose underlying conductive features, e.g. underlying portions of the metallization layer(s). The patterning may be performed using an acceptable process, such as by exposing the dielectric layer to light when it is a photosensitive material, or by etching using, for example, an anisotropic etch. If the dielectric layer is formed of a photosensitive material, it can be developed after the exposure.

The metallization layer(s) include conductive features such as conductive vias and/or conductive lines. The conductive vias extend through the dielectric layer(s), and the conductive lines extend along the dielectric layer(s). As an example to form a metallization layer, a seed layer (not separately illustrated) is formed over the respective underlying features. For example, the seed layer can be formed on a respective dielectric layer and in the openings through the respective dielectric layer, or can be formed on the TSVs 52 or the substrate 51. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as Physical Vapor Deposition (PVD) or the like. A photoresist is then formed and patterned on the seed layer. The photoresist may be formed by spin coating or the like and may be exposed to light for patterning. The pattern of the photoresist corresponds to the metallization layer. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form the metallization layer. This is an example, and other techniques or materials may be used to form the redistribution structure 58. For example, in some cases, the redistribution structure 58 may comprise other passivation layers or insulating layers.

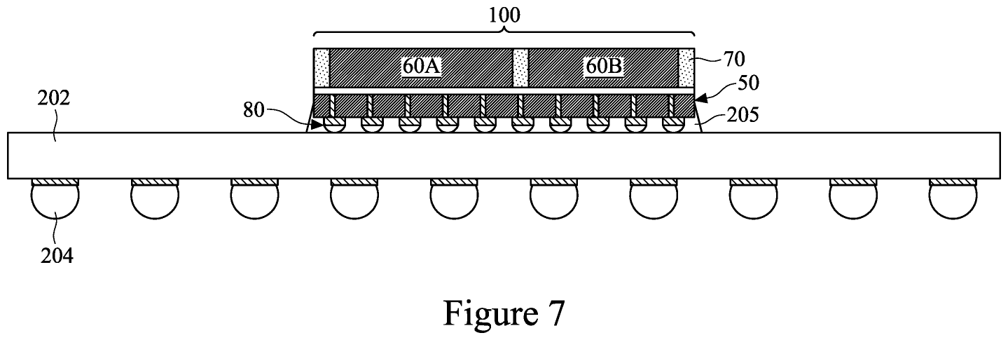

In some embodiments, conductive connectors 80 may be formed on the redistribution structure 58 for attaching the package components 100 to an external component (e.g., the package substrate 202 of FIG. 7). In some embodiments, the conductive connectors 80 optionally include under bump metallurgies (UBMs). The UBMs have bump portions on and extending along the major surface of the redistribution structure 58, and have via portions extending through the redistribution structure 58 to physically and electrically connect to the metallization layer(s). The UBMs may comprise one or more conductive materials such as metal, such as copper, titanium, tungsten, aluminum, or the like. The UBMs may be formed of the same material(s) as the metallization layer(s). In some embodiments, the UBMs have a different size than the metallization layer(s).

In some embodiments, the conductive connectors 80 comprise connectors, which may be formed on the UBMs (if present). The connectors may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The connectors may include a conductive material such as solder, copper, aluminum, gold, nickel, silver, palladium, tin, the like, or a combination thereof. In some embodiments, the connectors are formed by initially forming a layer of solder through evaporation, electroplating, printing, solder transfer, ball placement, or the like. Once a layer of solder has been formed on the structure, a reflow may be performed in order to shape the material into desired bump shapes. In another embodiment, the connectors comprise metal pillars (such as copper pillars) formed by sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In FIG. 6, a singulation process is performed to separate the package regions 100′ into individual package components 100, in accordance with some embodiments. The singulation process may comprise a sawing process, an etching process, or any other suitable singulation process. In this manner, a package component 100 comprising multiple devices 60 may be formed. The process described in FIGS. 1-6 for forming package components 100 is an example, and a package component 100 may have a different configuration or may be formed using different process steps than shown. All suitable materials, techniques, or variations thereof are considered within the scope of the present disclosure.

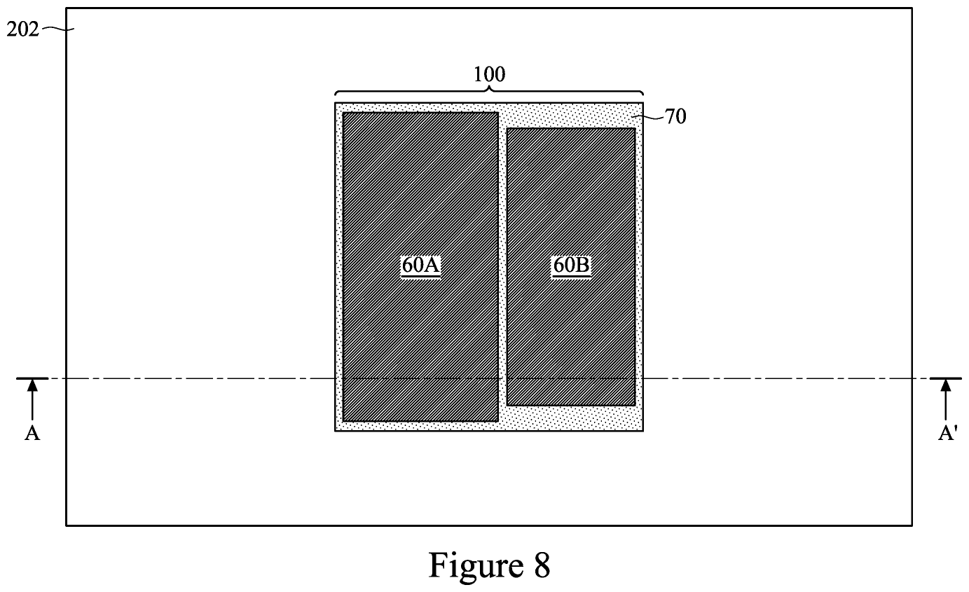

In FIGS. 7 and 8, a package component 100 is attached to a package substrate 202, in accordance with some embodiments. FIG. 7 illustrates a cross-sectional view, and FIG. 8 illustrates a schematic plan view. In some cases, the cross-sectional view of FIG. 7 may be along a cross-section similar to the reference cross-section A-A′ shown in FIG. 8. The package component 100 may be similar to the package components 100 described for FIGS. 1-6. For clarity, a simplified drawing of a package component 100 is shown in FIG. 7 and in some subsequent figures. As shown in FIG. 8, the package component 100 comprises two devices 60, device 60A and device 60B, that are surrounded by a molding material 70. However, in other embodiments, the number, arrangement, or dimensions of the devices 60 of a package component 100 may be different than shown.

The package substrate 202 may be any suitable substrate or component, such as a device die, a redistribution structure, an interposer, a wafer, a semiconductor substrate, a panel, a core substrate, a printed circuit board (PCB), a motherboard, a main board, or the like. The package substrate 202 may comprise conductive features such as conductive lines, conductive vias, conductive pads, or the like (not illustrated) to make electrical interconnections within the package substrate 202 and to make electrical connections to the package component 100 or other components attached to the package substrate 202. The package substrate 202 may or may not comprise active devices and/or passive devices. In some embodiments, conductive connectors 204 are formed on the package substrate 202, which may be similar to the conductive connectors 80 described previously, though other conductive connectors 204 are possible.

In some embodiments, the package component 100 is bonded to the package substrate 202 by aligning the conductive connectors 80 with corresponding conductive features (not illustrated) of the package substrate 202. For example, the conductive features of the package substrate 202 may be conductive pads, conductive pillars, solder bumps, or the like. The conductive connectors 80 are then placed into contact with the corresponding conductive features. Then, a reflow process may be performed to bond the conductive connectors 80 to the conductive features of the package substrate 202. In this manner, the package component 100 may be physically and electrically connected to the package substrate 202. In other embodiments, the package component 100 may be bonded to the package substrate 202 using fusion bonding, such as dielectric-to-dielectric bonding and/or metal-to-metal bonding.

Still referring to FIG. 7, an optional underfill 205 may be deposited between the package component 100 and the package substrate 202, in accordance with some embodiments. The underfill 205 may surround the conductive connectors 80. In some cases, the underfill 205 is cured using a thermal process, an ultraviolet (UV) process, or the like. In other embodiments, an underfill 205 is not formed.

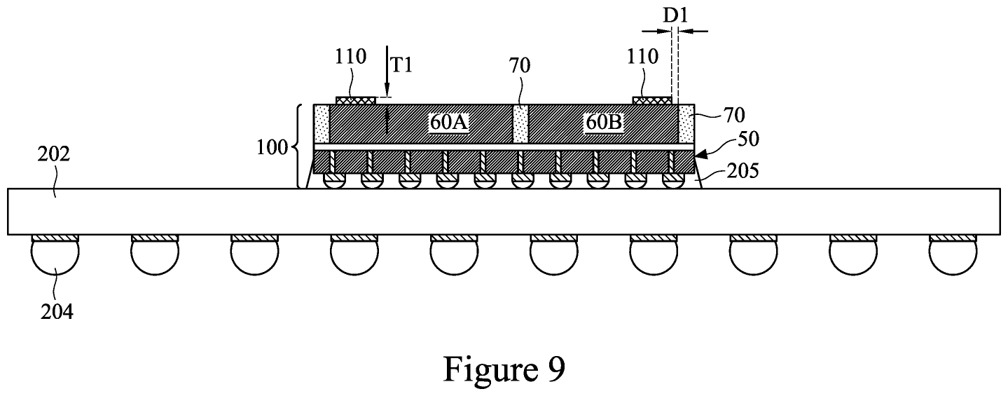

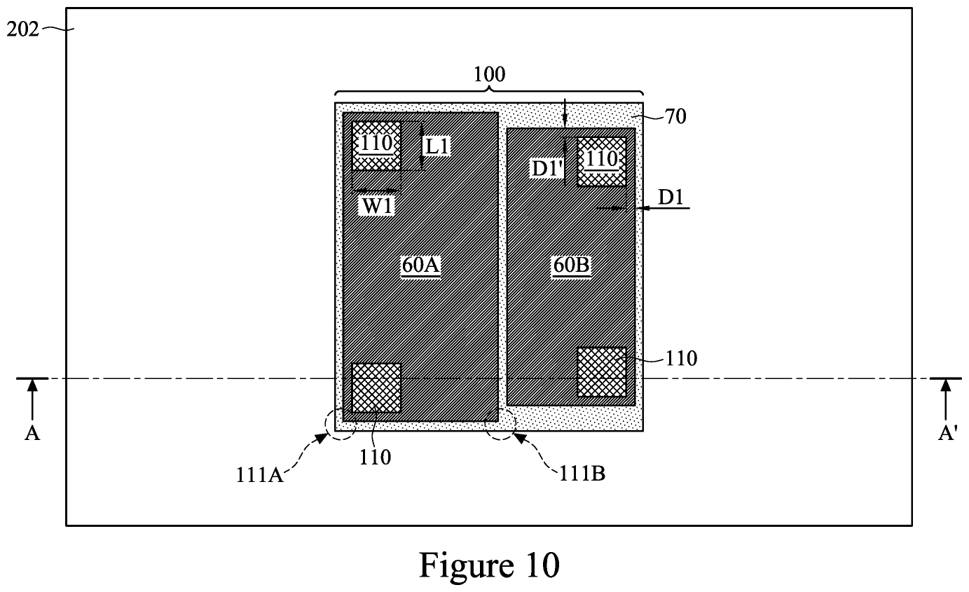

In FIGS. 9 and 10, reinforcement structures 110 are attached to the devices 60A-B, in accordance with some embodiments. FIG. 9 illustrates a cross-sectional view, and FIG. 10 illustrates a plan view, in accordance with some embodiments. The reinforcement structures 110 comprise one or more structures that are attached to the devices 60A-B in order to provide additional support during subsequent processing steps.

In some cases, the Coefficient of Thermal Expansion (CTE) of the devices 60A-B and the package substrate 202 may be different. This CTE mismatch causes different thermal expansion between the devices 60A-B and the package substrate 202, which can result in stress within the package component 100 when the package component 100 is heated during subsequent processing steps. In some cases, this “thermal stress” due to CTE mismatch may be larger in regions of the package component 100 within which the molding material 70 provides less rigid support during thermal expansion. For example, in some cases, the thermal stress may be larger in “corner regions” that are near the corners of the devices 60A-B, examples of which are indicated in FIG. 10 for device 60A as corner regions 111A-B. In some cases, the corner region 111A may be considered an “outer corner region” of the device 60A because it is relatively close to the edge of the package component 100, and the corner region 111B may be considered an “inner corner region” of the device 60A because it is relatively close to the center of the package component 100. In some cases, outer corner regions (e.g., corner region 111A) may be regions that are near both a corner of a device 60 and a corner of the package component 100, and inner corner regions (e.g., corner region 111B) may be regions that are near a corner of a device 60 but are away from a corner of the package component 100. In some cases, the thermal stress in these corner regions may cause cracking or other stress-stress damage within the package component 100, such as cracking of the wafer 50. In some cases, outer corner regions may be more prone to thermal stress than inner corner regions.

Accordingly, reinforcement structures 110 as described herein may be attached to the devices 60A-B to provide supplementary support during thermal expansion, reducing the chance of cracking or other stress-related damage. The rigid support against thermal stresses provided by the reinforcement structures 110 can reduce stresses within the package component 100 and/or the package substrate 202. The reinforcement structures 110 may reduce the CTE mismatch between upper portions of the package component 100 and the package substrate 202, which can reduce the chance of cracking due to thermal stress. For example, in some cases, the use of reinforcement structures 110 as described herein can reduce the chance of cracking of the wafer 50 due to thermal stress by more than 5%. In this manner, the reliability and/or yield of a package may be improved.

The reinforcement structures 110 may be attached to top surfaces of the devices 60A-B using an adhesive, an epoxy, or the like. In some embodiments, the reinforcement structures 110 may be rigid structures formed of one or more rigid materials, such a stainless steel, another metal, a ceramic, or the like. In some embodiments, the reinforcement structures 110 may have a CTE larger than the CTE of the devices 60, such as a CTE larger than about 2.6 ppm/° C., though other CTEs are possible. In some embodiments, the reinforcement structures 110 may have a Young's Modulus larger than that of the package substrate 202, such as a Young's Modulus greater than about 15 GPa, though other values are possible. In some embodiments, the reinforcement structures 110 has a thickness T1 that is in the range of about 1 μm to about 1000 μm, though other thicknesses are possible. In some cases, a larger thickness T1 may provide more rigid support against thermal stress.

In some embodiments, a reinforcement structure 110 may be attached to a device 60 such that the reinforcement structure 110 does not overlap (e.g., extend over) or contact the molding material 70, in order to avoid effects due to deformation or shifting of the molding material 70 during a thermal process. In other words, the reinforcement structures 110 attached to a device 60 are contained within the “footprint” (e.g., the perimeter) of the device 60. The reinforcement structures 110 attached to a device 60 fully overlap the device 60 and are fully underlapped by the device 60 such that no portions of the reinforcement structures 110 protrude beyond the perimeter of the device 60, in some embodiments. Accordingly, a reinforcement structure 110 may be aligned with a sidewall of the underlying device 60 such that a sidewall of the reinforcement structure 110 and the sidewall of the device 60 are approximately flush, coplanar, or coterminous. In some cases, having a reinforcement structure 110 aligned with a sidewall of the underlying device 60 may most effectively provide rigid support against thermal stress. However, in other embodiments, a reinforcement structure 110 may be offset from a sidewall of the underlying device 60. In some embodiments, a sidewall of a reinforcement structure 110 and a sidewall of the underlying device 60 may be laterally separated by a distance D1 that is in the range of about 0.1 μm to about 100 μm. For embodiments in which a sidewall of a reinforcement structure 110 and a sidewall of the underlying device 60 are coplanar, the separation distance D1 may be about 0 μm. Other separation distances D1 are possible. The separation distance D1 may also be considered the separation distance between the molding material 70 and the reinforcement structure 110. In some cases, a smaller distance D1 may allow the reinforcement structure to provide more effective rigid support against thermal stress. FIG. 10 illustrates an example reinforcement structure 110 that is a distance D1 from a first sidewall of the device 60B and a distance D1′ from a second sidewall of the device 60B. The distances D1 and D1′ may be similar or different.

Referring to FIG. 10, a reinforcement structure 110 may have a width W1 in the range of about 1 μm to about 3300 μm and/or a length L1 in the range of about 1 μm to about 33000 μm, in accordance with some embodiments, though other dimensions are possible. In some embodiments, a single reinforcement structure 110 has dimensions less than that of the underlying device 60. For example, the width W1 may be between about 1 μm and about the width of the underlying device 60, and/or the length L1 may be between about 1 μm and about the length of the underlying device 60. In some embodiments, for two reinforcement structures 110 adjacent a same side of the underlying device 60, the combined lengths of the two reinforcement structures 110 may be between about 2 μm and about the length of that side of the underlying device 60. For example, in some embodiments, two reinforcement structures 110 adjacent a same side of the underlying device 60 may both have a length that is about half of the length of that side. Other combinations of lengths or widths are possible, and reinforcement structures 110 having various shapes may have various dimensions. In some embodiments, reinforcement structures 110 may have any suitable dimensions that avoid overlapping the molding material 70, though some overlap of the molding material 70 may be present or possible in some cases. In some embodiments, the top surface of a device 60 is not fully covered (or almost fully covered) by one or more reinforcement structures 110 in order to avoid introducing thermal stress due to the rigidity of the reinforcement structure(s) 110.

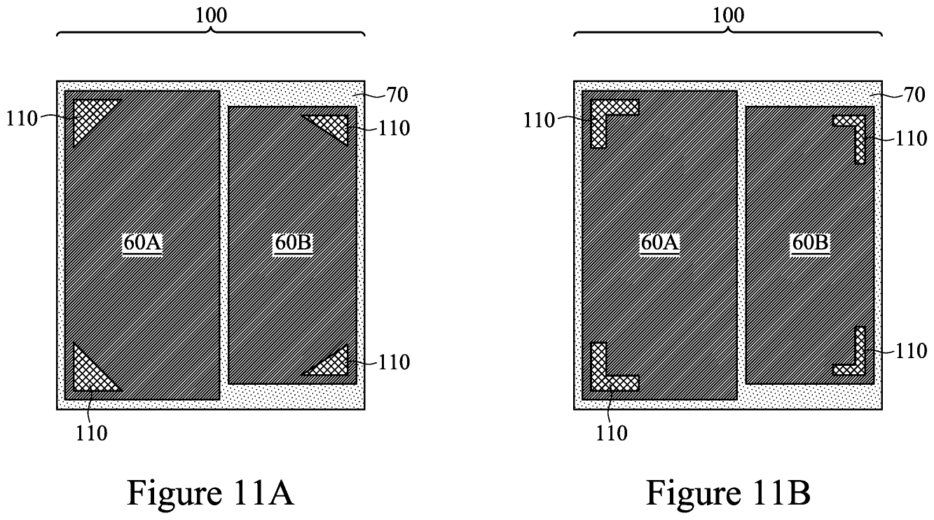

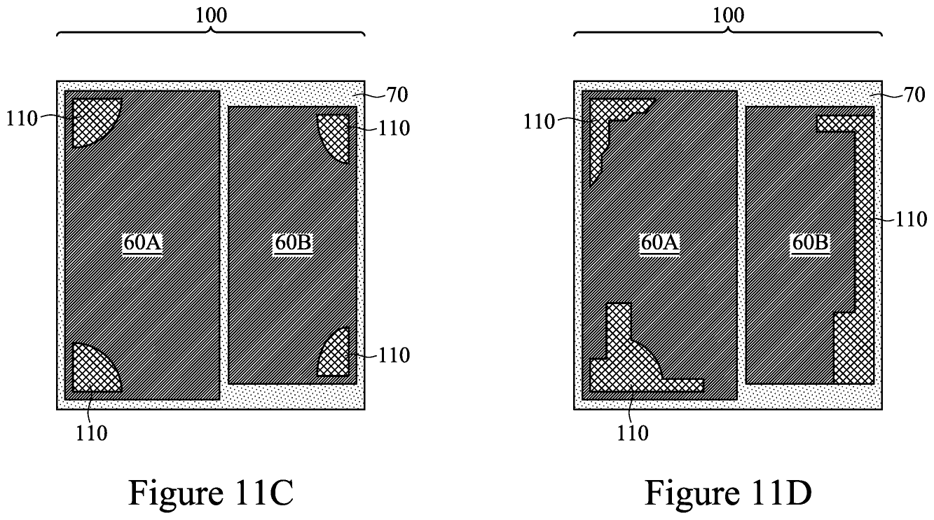

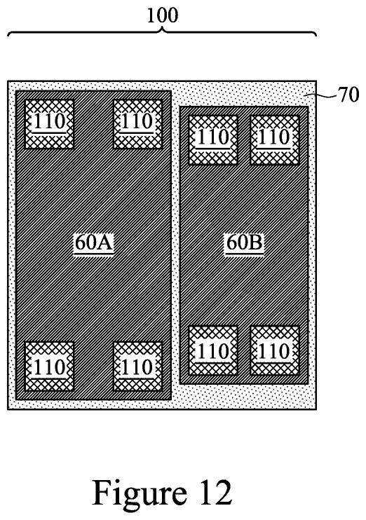

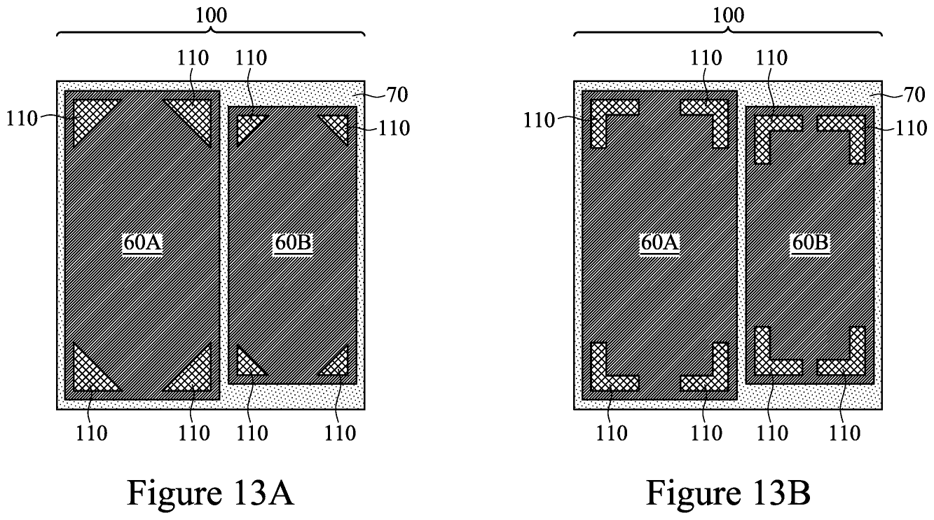

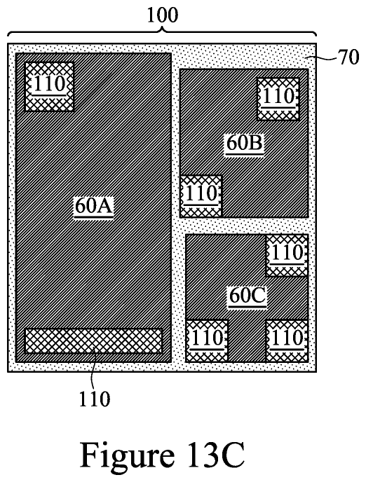

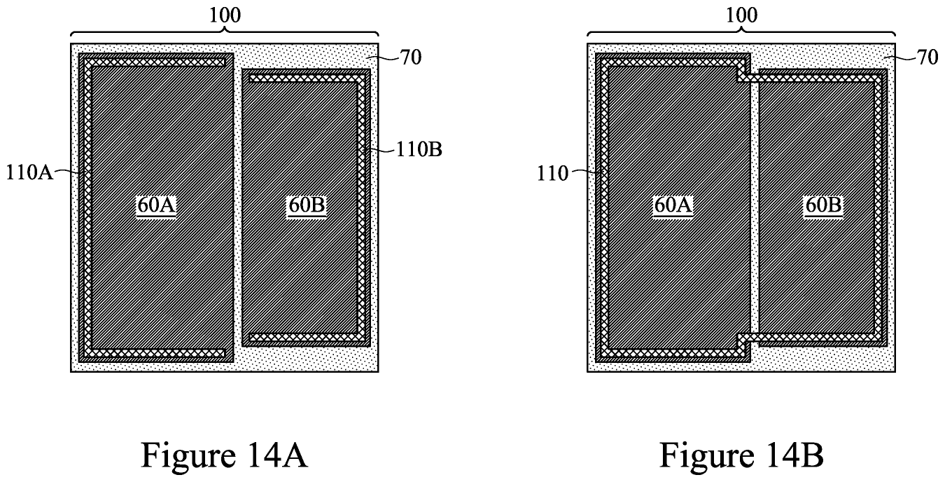

FIG. 10 illustrates an embodiment in which the reinforcement structures 110 are four rectangular structures attached near the four outer corners of devices 60A and 60B. In other embodiments, the reinforcement structures 110 may have any other suitable shapes and/or may be attached in any other suitable locations. In other embodiments, another number of reinforcement structures 110 may be attached to the package component 100. The shapes, locations, arrangements, or numbers of reinforcement structures 110 may depend on or be determined by the particular application, the particular structure of the package component 100, or the particular structure of the package comprising the package component 100. As non-limiting examples for illustrative purposes, FIGS. 11A through 14B illustrate plan views of reinforcement structures 110 on package components 100, in accordance with some embodiments. FIGS. 11A-11D illustrate embodiments comprising reinforcement structures 110 of different shapes, and FIGS. 12 and 13A-13C illustrate embodiments comprising different numbers of reinforcement structures 110. FIGS. 14A-14B illustrate embodiments comprising reinforcement structures 110 in ring-like configurations.

FIG. 11A illustrates an embodiment in which the reinforcement structures 110 have triangular shapes. As shown in FIG. 11A, in some embodiments, the reinforcement structures 110 may be shaped like right triangles in which the perpendicular sides are aligned with the sides of the devices 60. FIG. 11B illustrates an embodiment in which the reinforcement structures 110 are “L-shaped” structures. The two legs of an L-shape may have the same length and width or different lengths and/or widths. FIG. 11C illustrates an embodiment in which the reinforcement structures 110 are shaped approximately like quarter-circles or quarter-ellipses. As shown in FIG. 11C, the reinforcement structures 110 may have two perpendicular sides and one curved side. In other embodiments, the curved side of a reinforcement structure 110 may have another type of curve than a circular curve or an elliptical curve. These are examples, and the reinforcement structures 110 may have any suitable shapes. For example, differently-shaped reinforcement structures 110 may be attached to the same package component 100. FIG. 11D illustrates non-limiting examples of various irregular shapes that reinforcement structures 110 may have. As shown in FIG. 11D, a single reinforcement structure 110 may extend between opposite sides of a device 60, and a single reinforcement structure 110 may have multiple separation distances (e.g., D1 or D1′) from the molding material 70.

As shown in FIG. 12, reinforcement structures 110 may also be placed near the inner corners of the devices 60 (e.g., corner region 111B shown in FIG. 10) to provide rigid support against thermal stress in these regions. In this manner, cracking or other damage due to thermal stress from these regions may be avoided. In some cases, a reinforcement structure 110 may be placed near all four corners of a device 60. As additional non-limiting examples, FIG. 13A illustrates triangular reinforcement structures 110 placed near inner corners, and FIG. 13B illustrates L-shaped reinforcement structures 110 placed near inner corners. FIG. 13C illustrates an embodiment in which the package component 100 comprises three devices 60A-C. As shown in FIG. 13C, reinforcement structures 110 may or may not be placed near any corner of any device 60A-C. A reinforcement structure 110 may also extend between an outer corner and an inner corner, in some embodiments. FIG. 13C is also intended to be an illustrative and non-limiting example.

FIGS. 14A and 14B illustrate non-limiting embodiments in which one or more reinforcement structures 110 are arranged in a ring-like configuration. The ring-like configuration may comprise one or more reinforcement structures 110 that extend mostly or fully along the outer perimeter of the devices 60. For example, FIG. 14A illustrates an embodiment in which a single reinforcement structure 110A extends along the outer perimeter of the device 60A, and a single reinforcement structure 110B extends along the outer perimeter of the device 60B. For example, the reinforcement structure 110A extends along three sides of the device 60A, and the reinforcement structure 110B extends along three sides of the device 60B. The reinforcement structures 110A and 110B together are arranged in a ring-like configuration with gaps between the devices 60A and 60B, such that the reinforcement structures 110A-B do not extend over the molding material 70. In other embodiments, a single ring-like reinforcement structure 110 may be used, as shown in FIG. 14B. The single reinforcement structure 110 of FIG. 14B extends over both devices 60A-B and extends over the molding material 70 between the devices 60A-B. In some cases, the distance that the ring-like reinforcement structure 110 extends over the molding material 70 may be minimized to avoid thermal effects from the molding material 70. In some embodiments, a separation distance between the devices 60A and 60B may be in the range of about 10 μm to about 33000 μm, though other distances are possible. These are examples, and ring-like reinforcement structures 110 may have other thicknesses, varying thicknesses, or other configurations than shown. In some cases, the use of reinforcement structure(s) 110 in a ring-like configuration may provide rigid support against thermal stress near outer corners, along sidewalls, and near inner corners, which can reduce the risk of thermal stress damage.

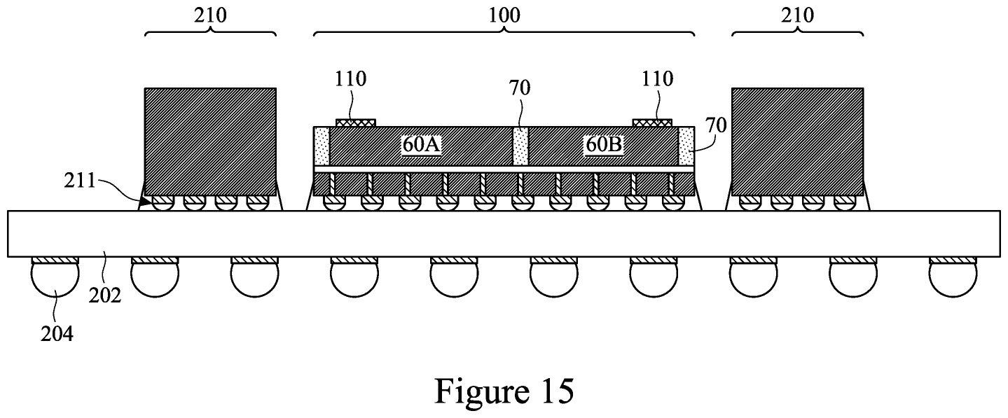

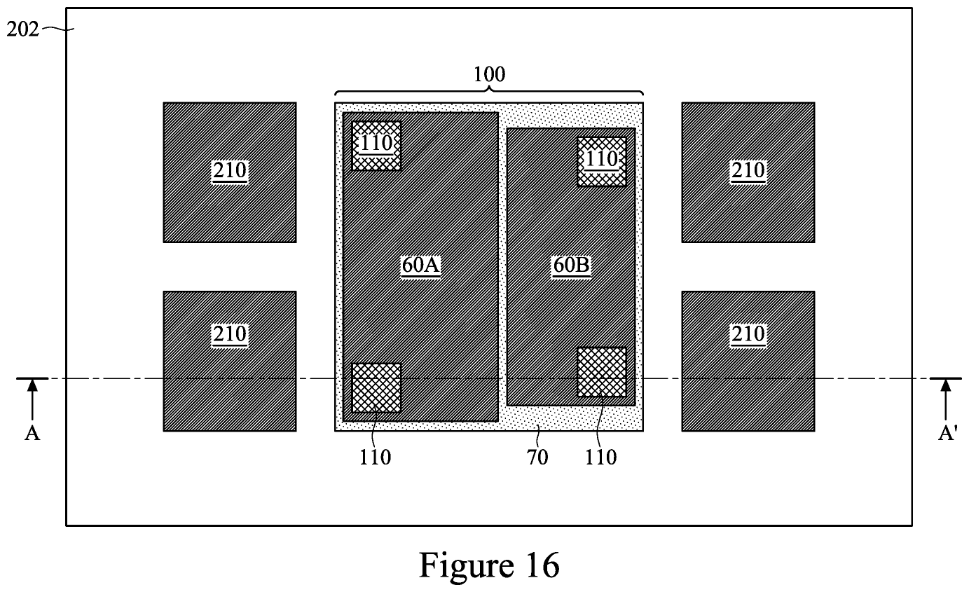

Following the process steps shown in FIGS. 9-10, FIGS. 15 and 16 illustrate the attachment of package components 210 to the package substrate 202, in accordance with some embodiments. FIG. 15 illustrates a cross-sectional view, and FIG. 16 illustrates a plan view. The package components 210 may be dies, chips, packages, or the like, and may be similar to the devices 60 or package components 100 described previously. For example, in some embodiments, the package components 210 may comprise a memory die, such as a dynamic random access memory (DRAM) die, static random access memory (SRAM) die, a hybrid memory cube (HMC) die, a high bandwidth memory (HBM) die, or the like. Other types of package components 210 are possible. The package components 210 attached to the package substrate 202 may be similar or different types of package components 210, and may have a different number or arrangement than shown.

The package components 210 may be attached to the package substrate 202 using techniques similar to those described for attaching the package component 100, in some embodiments. For example, conductive connectors 211 of the package components 210 may be placed on corresponding conductive features of the package substrate 202, and then a reflow process may be performed to bond the conductive connectors to the package substrate 202. In some cases, the reflow process may comprise a thermal process in the range of about 150° C. to about 250° C., though other temperatures are possible. In some cases, the reflow process may cause thermal stress within the package component 100, which the reinforcement structures 110 may provide rigid support against, reducing the chance of thermal stress damage during the reflow process. In some embodiments, an underfill material may be deposited between the package components 210 and the package substrate 202, which may be similar to the underfill 205 described previously.

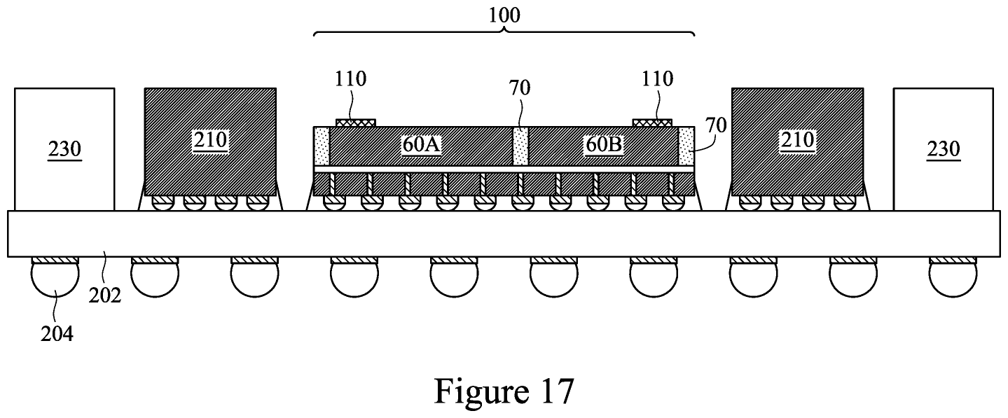

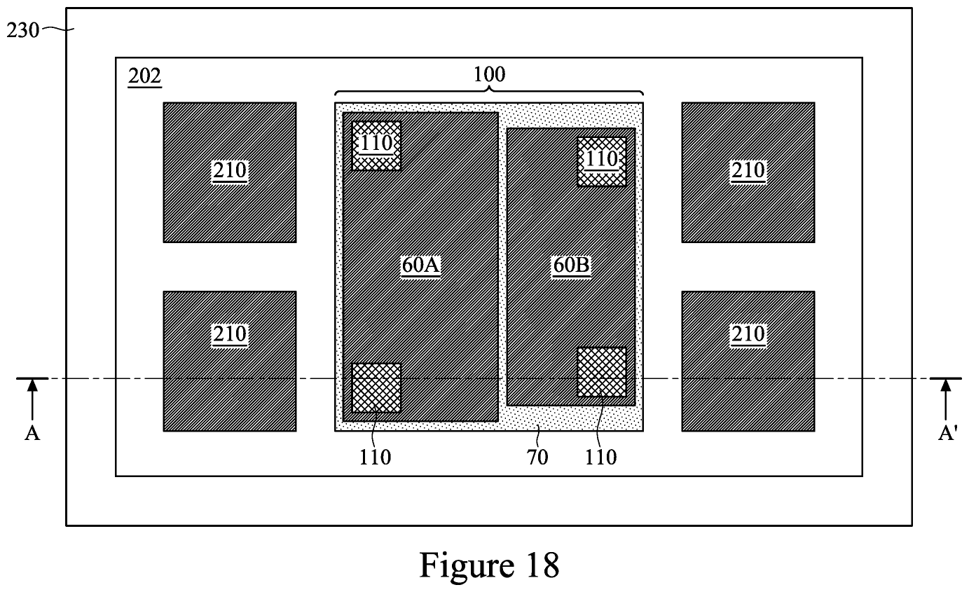

FIGS. 17 and 18 illustrate the attachment of a support structure 230 to the package substrate 202, in accordance with some embodiments. FIG. 17 illustrates a cross-sectional view, and FIG. 18 illustrates a plan view. The support structure 230 may be a rigid structure that is attached to the package substrate 202 to provide structural support and reduce warping. As shown in FIG. 18, the support structure 230 may be a ring-like structure, such as a stiffener ring or the like. The support structure 230 may comprise one or more suitable materials such as a metal, a ceramic, or the like. The support structure 230 may be attached to the package substrate 202 using an adhesive, an epoxy, or the like. In other embodiments, the support structure 230 comprises multiple pieces that are separately attached to the package substrate 202. FIG. 17 illustrates the support structure 230 having approximately the same height above the package substrate 202 as the package components 210, but in other embodiments, the support structure may have a height that is greater than or smaller than the package components 100 and/or the package components 210.

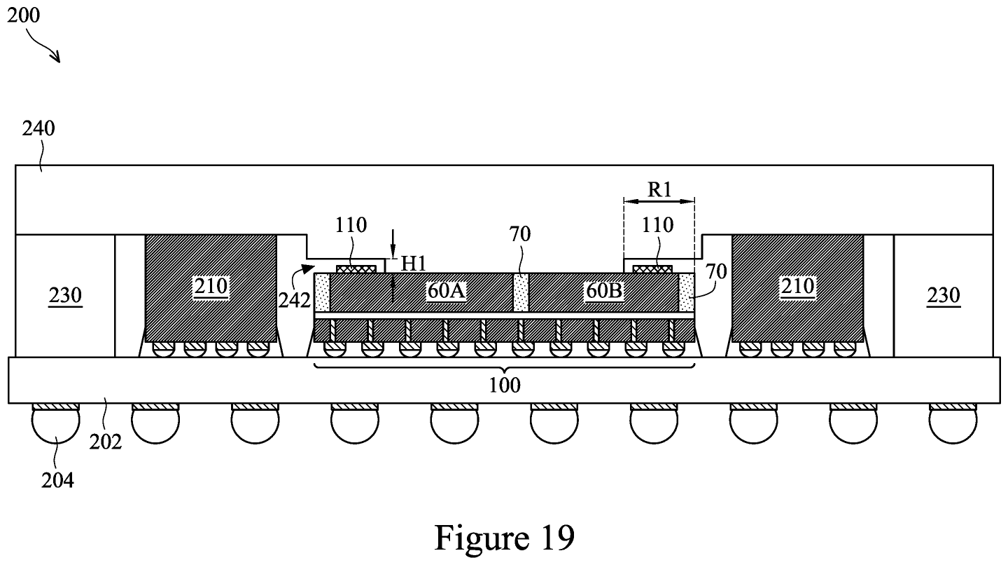

FIG. 19 illustrates the attachment of a lid 240 to the support structure 230, forming a package 200, in accordance with some embodiments. The lid 240 covers and protects the package component 100 and the package components 210. In some embodiments, portions of the lid 240 are attached to the package component 100 and/or the package components 210 to facilitate heat dissipation from the package component 100 and/or the package components 210. In some cases, a thermal interface material (TIM, not illustrated) or the like may be deposited between the lid 240 and the package component 100 and/or the package components 210 to facilitate heat transfer. Accordingly, where the lid 240 is described as contacting the package components 100/210 herein, it should be understood that a TIM or the like may or may not be present between the lid 240 and the package components 100/210. In some cases, the profile of the underside of the lid 240 may have a shape that corresponds to different heights of the package components 100 and package components 210, as shown in FIG. 19. In some embodiments, the lid 240 may have a thickness in the range of about 100 μm to about 5000 μm, though other thicknesses and multiple thicknesses are possible. The lid 240 may be attached to the support structure 230 using an adhesive, an epoxy, or the like. In other embodiments, the support structure 230 is part of the lid 240, and thus the lid 240 is attached directly to the package substrate 202. The lid 240 may be a material such as metal (e.g., steel, copper, etc.) ceramic, or the like. In some embodiments, the CTE of the lid 240 is about the same as or less than the CTE of the reinforcement structures 110.

In some embodiments, the profile of the underside of the lid 240 is shaped such that the lid 240 does not physically contact the reinforcement structures 110. In this manner, the lid 240 can account for thermal expansion of the reinforcement structures 110 and avoid generating additional thermal stress from contact between the reinforcement structures 110 and the lid 240. For example, as shown in FIG. 19, the underside of the lid 240 may have recesses 242 that are shaped to provide separation between the lid 240 and the reinforcement structures 110 while still allowing the underside of the lid 240 to contact the package component 100. In some embodiments, a reinforcement structure 110 may be laterally surrounded by the lid 240. In some embodiments, the lid 240 may be separated from a reinforcement structure 110 by a distance in the range of about 10 μm to about 1000 μm, though other distances are possible. In some embodiments, the height H1 of a recess 242 is greater than the thickness T1 of the reinforcement structure(s) 110 within it. In some embodiments, a recess 242 extends a distance R1 over the package component 100, and the distance R1 is greater than a corresponding width (e.g., W1) or length (e.g., L1) of the reinforcement structure 110 within the recess 242.

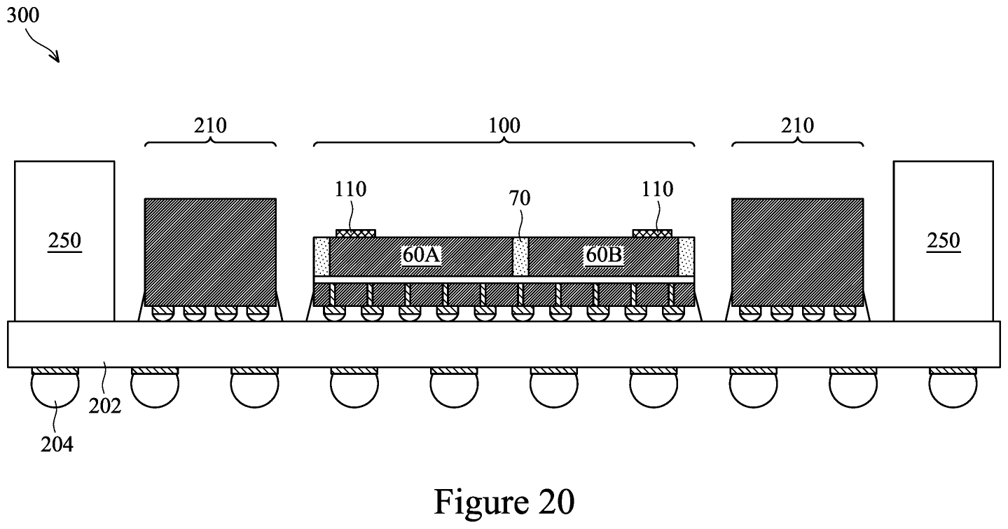

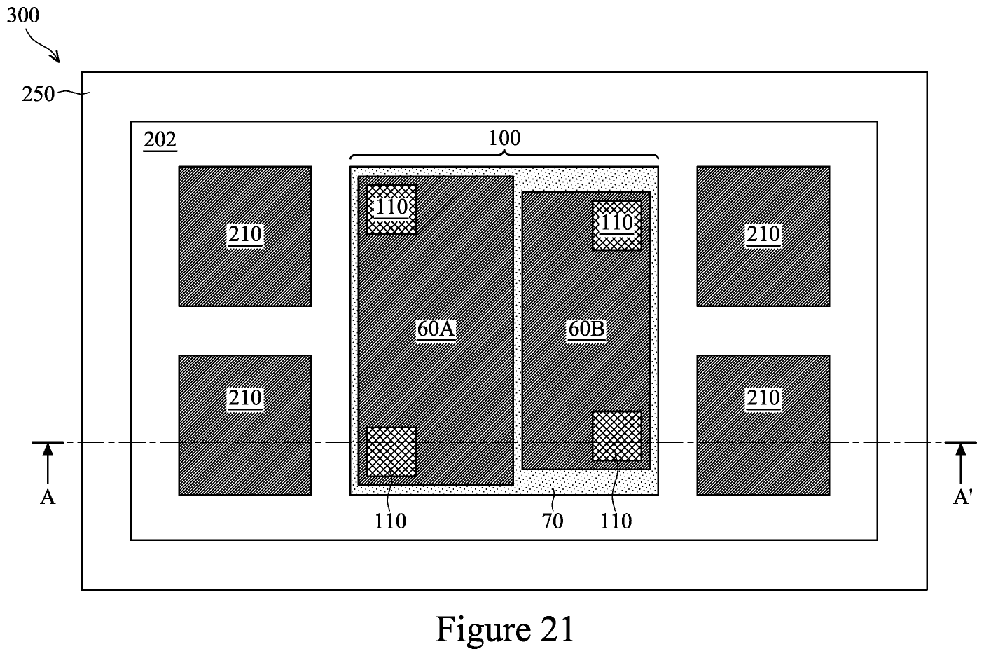

FIGS. 20 and 21 illustrate a package 300 comprising a support ring 250, in accordance with some embodiments. FIG. 20 illustrates a cross-sectional view, and FIG. 21 illustrates a plan view. The package 300 is similar to the package 200 illustrated in FIG. 19, except that a support ring 250 is used instead of a support structure 230 and a lid 240. The support ring 250 may be similar to the support structure of 230, in some cases. For example, in some embodiments, the support ring 250 may be a stiffener ring or the like. The support ring 250 may be attached to the package substrate 202 using an adhesive, an epoxy, or the like. The support ring 250 may comprise one or more rigid materials, such as metal, ceramic, plastic, or the like. In some embodiments, a height of the support ring 250 is greater than that of the package component 100 and/or the package components 210. In other embodiments, a height of the support ring 250 may be about the same as or less than a height of the package components 100/210.

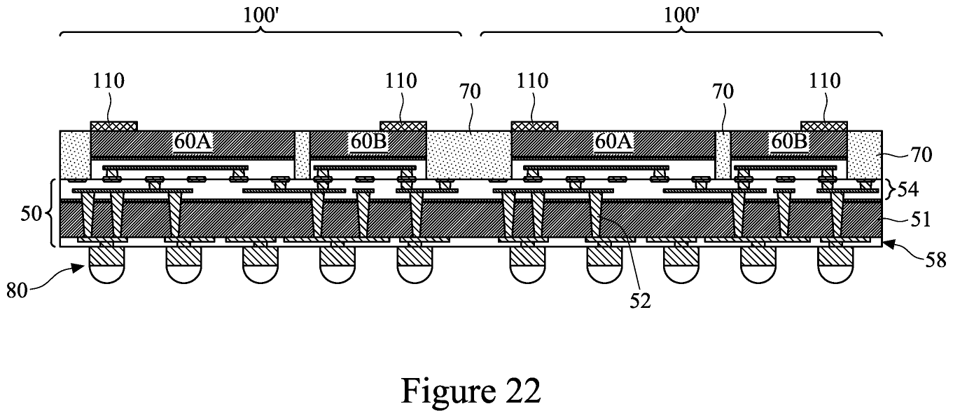

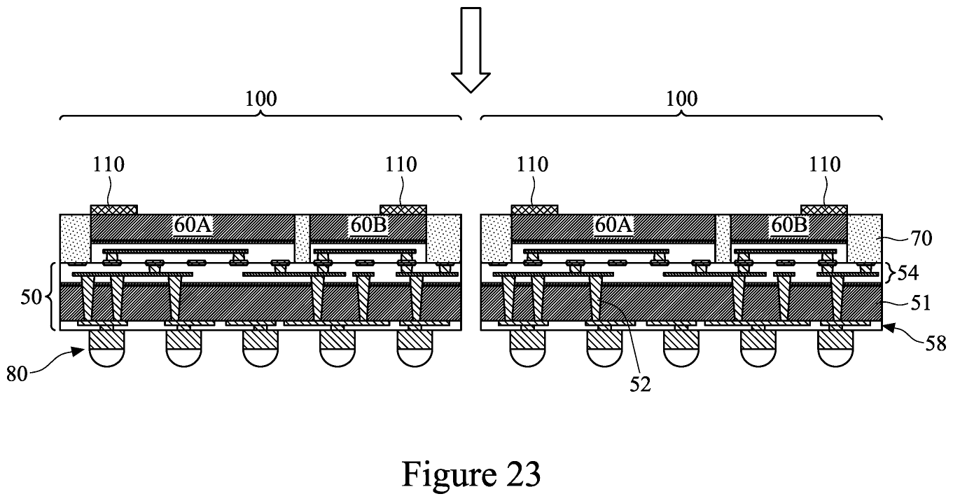

In FIGS. 1-9 described above, the reinforcement structures 110 are attached to the package component 100 after attachment of the package component 100 to the package substrate 202. However, in other embodiments, the reinforcement structures 110 are formed on the package component 100 prior to attachment of the package component 100 to the package substrate 202. As an example, FIGS. 22-23 illustrate intermediate steps in the formation of reinforcement structures 110 on package components 100, in accordance with some embodiments. The package components 100 may be similar to those described for FIGS. 1-6, and the reinforcement structures 110 may be similar to those described previously. FIGS. 22-24 describe reinforcement structures 110 formed on a structure similar to that shown in FIG. 5, but reinforcement structures 110 may be formed after any suitable process step prior to attachment of the package component 100 to the package substrate 202.

In FIG. 22, reinforcement structures 110 are formed on package regions 100′ prior to singulation into package components 100. Accordingly, the reinforcement structures 110 may be formed on a structure similar to that shown in FIG. 5. In some embodiments, the reinforcement structures 110 may be attached to top surfaces of the devices 60 using an adhesive, an epoxy, or the like.

In other embodiments, the reinforcement structures 110 are metallic structures that are formed directly onto top surfaces of the devices 60. The reinforcement structures 110 may comprise a metal material deposited using a suitable technique such as CVD, PVD, Atomic Layer Deposition (ALD), plating, or the like. The reinforcement structures 110 may comprise a metal such as copper, aluminum, gold, silver, iron, tin, an alloy thereof, a combination thereof, or the like. In some embodiments, the reinforcement structures 110 may be formed by depositing metal material using suitable deposition techniques and then patterning the metal material using suitable photolithography and etching techniques. In other embodiments, a seed layer (not separately illustrated) is first deposited over the top surfaces of the devices 60 and molding material 70. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as PVD or the like. A photoresist is then formed and patterned on the seed layer. The photoresist may be formed by spin coating or the like and may be exposed to light for patterning. The pattern of the photoresist corresponds to the reinforcement structures 110. The patterning forms openings through the photoresist to expose the seed layer. A metal material is formed in the openings of the photoresist and on the exposed portions of the seed layer using a plating process, such as electroplating, electroless plating, or the like. Then, the photoresist and portions of the seed layer on which the metal material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and metal material form the reinforcement structures 110. This is an example, and other techniques or materials may be used to form the reinforcement structures 110.

In FIG. 23, a singulation process is performed to separate the package regions 100′ into individual package components 100 with reinforcement structures 110, in accordance with some embodiments. The singulation process may be similar to that described previously for FIG. 6.

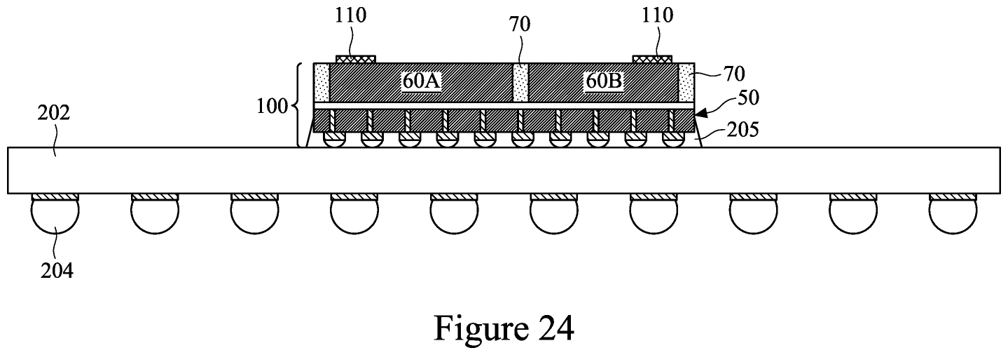

In FIG. 24, a package component 100 with reinforcement structures 110 is attached to a package substrate 202. The package component 100 with reinforcement structures 110 may be attached to the package substrate 202 in a manner similar to that described previously for FIG. 7. After attaching the package component 100 with reinforcement structures 110 to the package substrate 202, the resulting structure of FIG. 24 is similar to the structure shown previously in FIG. 9. Subsequent processing may then be performed to form a package comprising the package component 100 with reinforcement structures 110, which may use materials or techniques similar to those described previously for FIGS. 15-21. Other materials or process steps are possible.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments described herein may achieve advantages. Forming reinforcement structures on package components as described herein can reduce the chance of stress damage due to thermal expansion. For example, the reinforcement structures can reduce thermal stress near corners of devices within a package component. The reinforcement structures can reduce thermal stress damage within a package component due to CTE mismatch between devices of the package component and the package substrate to which the package component is attached. The reinforcement structures can prevent thermally-induced damage such as cracking of an interposer or other structures within the package component. In this manner, reliability and yield of a package component or a package may be improved.

In an embodiment of the present disclosure, a method includes attaching a first package component to a substrate, wherein the first package component includes an interposer; dies on the interposer; and a molding material surrounding the dies; and attaching reinforcement structures to top surfaces of the dies, wherein the molding material is free of the reinforcement structures. In an embodiment, the reinforcement structures of the reinforcement structures are respectively attached to corresponding corners of the dies of the dies. In an embodiment, the corresponding corners of the dies are corners of the dies that are laterally closer to edges of the interposer than to the center of the interposer. In an embodiment, the method includes attaching a lid to top surfaces of the dies, wherein the lid is free of physical contact with the reinforcement structures. In an embodiment, the method includes attaching a second package component to the substrate. In an embodiment, the method includes attaching a support ring to the substrate. In an embodiment, a coefficient of thermal expansion (CTE) of the reinforcement structures is greater than a CTE of the dies. In an embodiment, the reinforcement structures are attached to the top surfaces of the dies before the first package component is attached to the substrate.

In an embodiment of the present disclosure, a method includes attaching a component to a package substrate, wherein the component includes a first die; forming a first reinforcement structure on a first corner region of the first die, wherein the first reinforcement structure is fully underlapped by the first die; and forming a second reinforcement structure on a second corner region of the first die, wherein the second reinforcement structure is fully underlapped by the first die. In an embodiment, forming the first reinforcement structure on the first corner region of the first die includes attaching the first reinforcement structure to the first die using an adhesive. In an embodiment, forming the first reinforcement structure on the first corner region of the first die includes depositing a metal material on a top surface of the first die. In an embodiment, a sidewall of the first reinforcement structure and a sidewall of the first die are coplanar. In an embodiment, the component includes a molding material surrounding the first die, wherein the first reinforcement structure is laterally separated from the molding material by a distance in the range of 0.1 μm to 100 μm. In an embodiment, the component includes a second die, and the method includes forming a third reinforcement structure on a third corner region of the second die, wherein the second reinforcement structure is fully underlapped by the second die. In an embodiment, the first corner region is adjacent the third corner region.

In an embodiment of the present disclosure, a package includes an interposer attached to a package substrate; a first semiconductor die bonded to the interposer; a second semiconductor die bonded to the interposer; a first reinforcement structure attached to a top surface of the first semiconductor die, wherein the first reinforcement structure is adjacent a first side of the first semiconductor die; a second reinforcement structure attached to a top surface of the second semiconductor die, wherein the second reinforcement structure is adjacent a first side of the second semiconductor die, wherein the first side of the first semiconductor die faces away from the first side of the second semiconductor die; and a molding material on the interposer, wherein the molding material is separated from the first reinforcement structure and the second reinforcement structure. In an embodiment, the first reinforcement structure has a rectangular shape in a plan view. In an embodiment, the package includes a lid attached to the first semiconductor die and the second semiconductor die, wherein the lid includes a first recess corresponding to the first reinforcement structure and a second recess corresponding to the second reinforcement structure. In an embodiment, the first reinforcement structure includes a metal material or a ceramic material. In an embodiment, a length of the first reinforcement structure is less than half of a length of the first side of the first semiconductor die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
attaching a first package component to a substrate, wherein the first package component comprises:
an interposer;
a plurality of dies on the interposer; and
a molding material surrounding the plurality of dies; and
attaching a plurality of reinforcement structures to top surfaces of the plurality of dies, wherein the molding material is free of the plurality of reinforcement structures.

2. The method of claim 1, wherein the reinforcement structures of the plurality of reinforcement structures are respectively attached to corresponding corners of the dies of the plurality of dies.

3. The method of claim 2, wherein the corresponding corners of the dies are corners of the plurality of dies that are laterally closer to edges of the interposer than to the center of the interposer.

4. The method of claim 1 further comprising attaching a lid to top surfaces of the plurality of dies, wherein the lid is free of physical contact with the plurality of reinforcement structures.

5. The method of claim 1 further comprising attaching a second package component to the substrate.

6. The method of claim 1 further comprising attaching a support ring to the substrate.

7. The method of claim 1, wherein a coefficient of thermal expansion (CTE) of the plurality of reinforcement structures is greater than a CTE of the plurality of dies.

8. The method of claim 1, wherein the plurality of reinforcement structures are attached to the top surfaces of the plurality of dies before the first package component is attached to the substrate.

9. A method comprising:
attaching a component to a package substrate, wherein the component comprises a first die;
forming a first reinforcement structure on a first corner region of the first die, wherein the first reinforcement structure is fully underlapped by the first die; and
forming a second reinforcement structure on a second corner region of the first die, wherein the second reinforcement structure is fully underlapped by the first die.

10. The method of claim 9, wherein forming the first reinforcement structure on the first corner region of the first die comprises attaching the first reinforcement structure to the first die using an adhesive.

11. The method of claim 9, wherein forming the first reinforcement structure on the first corner region of the first die comprises depositing a metal material on a top surface of the first die.

12. The method of claim 9, wherein a sidewall of the first reinforcement structure and a sidewall of the first die are coplanar.

13. The method of claim 9, wherein the component comprises a molding material surrounding the first die, wherein the first reinforcement structure is laterally separated from the molding material by a distance in the range of 0.1 μm to 100 μm.

14. The method of claim 9, wherein the component comprises a second die, and further comprising forming a third reinforcement structure on a third corner region of the second die, wherein the second reinforcement structure is fully underlapped by the second die.

15. The method of claim 14, wherein the first corner region is adjacent the third corner region.

16. A package comprising:
an interposer attached to a package substrate;
a first semiconductor die bonded to the interposer;
a second semiconductor die bonded to the interposer;
a first reinforcement structure attached to a top surface of the first semiconductor die, wherein the first reinforcement structure is adjacent a first side of the first semiconductor die;
a second reinforcement structure attached to a top surface of the second semiconductor die, wherein the second reinforcement structure is adjacent a first side of the second semiconductor die, wherein the first side of the first semiconductor die faces away from the first side of the second semiconductor die; and
a molding material on the interposer, wherein the molding material is separated from the first reinforcement structure and the second reinforcement structure.

17. The package of claim 16, wherein the first reinforcement structure has a rectangular shape in a plan view.

18. The package of claim 16 further comprising a lid attached to the first semiconductor die and the second semiconductor die, wherein the lid comprises a first recess corresponding to the first reinforcement structure and a second recess corresponding to the second reinforcement structure.

19. The package of claim 16, wherein the first reinforcement structure comprises a metal material or a ceramic material.

20. The package of claim 16, wherein a length of the first reinforcement structure is less than half of a length of the first side of the first semiconductor die.
